(19) United States
(12) Patent Application Publication
(10) Pub. No.: US 2014/0002196 A1
(43) Pub. Date: Jan. 2, 2014

(54) METHOD AND SYSTEM FOR CONTROLLING THE FREQUENCY OF A HIGH POWER MICROWAVE SOURCE

(71) Applicant: Paul H. Leek, Willimantic, CT (US)

(72) Inventor: Paul H. Leek, Willimantic, CT (US)

(21) Appl. No.: 13/926,176

(22) Filed: Jun. 25, 2013

Related U.S. Application Data
(60) Provisional application No. 61/663,706, filed on Jun. 25, 2012.

(51) Int. Cl. H03L 7/00

(52) U.S. Cl. CPC H03L 7/00
USPC 331/6

(57) ABSTRACT

A method and system for controlling the frequency of one or more high power microwave sources is provided. The inventive system is made up of a high power linear accelerator, and connected thereto, one or more high power sources of microwaves. In operation, a sample of microwave power from the linear accelerator is used to provide a locking or drive signal for the high power source(s) of microwaves.

### RELATED APPLICATION

This application claims priority to U.S. Provisional Patent Application Ser. No. 61/663,706, filed Jun. 25, 2012, which is incorporated herein in its entirety by reference.

### TECHNICAL FIELD

The present invention generally relates to a method and system for controlling the frequency of a high power microwave source, and more particularly relates to a method and system that uses a high power linear accelerator to control the frequency of this microwave source.

### BACKGROUND AND SUMMARY OF THE INVENTION

High power sources of microwaves such as klystrons and magnetrons serve as the driving force for modern particle accelerators. A klystron is a specialized linear-beam vacuum tube that is used as an amplifier at microwave (and radio) frequencies. As such, the klystron needs an external source of microwaves to drive it. This source must be several hundreds of watts and tunable. Typical klystrons at 3 gigahertz (Ghz) can provide up to 30 megawatts (MW) of peak power and up to 250 kilowatts (kW) of average power. Available power at other frequencies is higher at lower frequencies and lower at higher frequencies. This is due to the requirement that the elements are resonant entities preferably at the fundamental. At higher frequencies the wavelength is smaller and the cavities are smaller. Thus the overall size is smaller with less power handling capability.

A magnetron is a high-powered vacuum tube that generates microwaves using the interaction of a stream of electrons with a magnetic field. Many accelerators use a magnetron as frequency source. A magnetron is usually smaller and thus has a lower power capability. A magnetron, however, has two advantages. It is usually less expensive and it is self-excited. This means that the magnetron is an oscillator and thus needs no external microwave drive. Although the magnetron is a self-excited oscillator it is susceptible to frequency modification by the external connection. This is referred to as frequency ‘pulling’. Magnetrons can be locked to a local oscillator by injecting a low power signal into the magnetron output circuit.

Linear accelerators are resonant structures with a high Q. The required drive frequency is very high power, several megawatts, and high frequency. The required frequency must be provided within a very narrow range, typically less than 0.001% of the optimum frequency.

Several systems have been used to maintain this close frequency using auxiliary tuned cavities or by comparing the reflected radio frequency (RF) power phase to the incoming RF power. None of these systems have proven to be completely reliable. Many use small sampling signals which can be swamped by the large pulse signals generated by the power generator. In addition, these systems use microwave diodes which deteriorate with age in such a high radiation environment.

The present invention serves to address these drawbacks by providing a new frequency control which uses the accelerator itself as the control element.

The present invention more particularly provides a system comprising a high power linear accelerator (i.e., resonant/standing wave, traveling wave), and connected thereto, one or more high power sources of microwaves, wherein a sample of microwave power from the linear accelerator is used to provide a locking or drive signal for the one or more high power sources of microwaves.

In an exemplary embodiment of the inventive system, the linear accelerator is a resonant or standing wave accelerator.

When the microwave power source(s) is an amplifier (e.g., a klystron or an amplitron), the microwave power sample from the linear accelerator is used to drive the amplifier, the inventive system further comprising:
a pick-up probe fitted into an accelerating cavity of the linear accelerator to collect the microwave power sample or feedback signal along a center mode or main Pi/2 mode of the linear accelerator, the pick-up probe in communication with the amplifier via a feedback line;
a tuned cavity or band pass filter in the feedback line for limiting feedback to the main Pi/2 mode of the linear accelerator;
an adjustable phase shifter in the feedback line for adjustably providing a 360 degree range of phase shift to the feedback signal;
an attenuator in the feedback line for adjusting amplitudes of the feedback signal; and
a high power circulator (e.g., a 3-port or 4-port circulator) having one or more ports terminating in a dummy load, which is in communication with both the linear accelerator and the amplifier, and which is used as an isolator to attenuate reflected power, thereby protecting the amplifier.

When the microwave power source(s) is a self oscillating tube (e.g., a magnetron), the microwave power sample from the linear accelerator is used to lock the tube's resonant frequency.

In a first such embodiment, a 4-port circulator is used to feed the feedback signal (i.e., locking signal) into the self oscillating tube, the inventive system further comprising:
a 4-port circulator having a first port in communication with the self oscillating tube, a second port in communication with the linear accelerator, a third port having a dummy load to attenuate reflected power, and a fourth port in communication with a feedback line;
a pick-up probe fitted into an accelerating cavity of the linear accelerator to collect the microwave power sample or feedback signal along a center mode or main Pi/2 mode of the linear accelerator, the pick-up probe in communication with the 4-port circulator via the feedback line;
a tuned cavity or band pass filter in the feedback line for limiting feedback to the main Pi/2 mode of the linear accelerator;
an adjustable phase shifter in the feedback line for adjustably providing a 360 degree range of phase shift to the feedback signal; and
either a coaxial isolator or circulator in the feedback line, which terminates in a dummy load, which also serves to attenuate reflected power.

In a second such embodiment, two 3-port circulators are used, the first 3-port circulator being used to feed the feedback or locking signal into the self oscillating tube, the system further comprising:
a first 3-port circulator having a first port in communication with the self oscillating tube, a second port, and a third port in communication with a feedback line;
a second 3-port circulator having a first port in communication with the second port of the first 3-port circulator, a second port in communication with the linear accelerator, and a third port terminating in a dummy load to attenuate reflected power;
a pick-up probe fitted into an accelerating cavity of the linear accelerator to collect the microwave power sample or feedback signal along a center mode or main Pi/2 mode of the linear accelerator, the pick-up probe in communication with the third port of the first 3-port circulator via the feedback line;
a tuned cavity or band pass filter in the feedback line for limiting feedback to the main Pi/2 mode of the linear accelerator;
an adjustable phase shifter in the feedback line for adjustably providing a 360 degree range of phase shift to the feedback signal; and
either a coaxial isolator or circulator in the feedback line, which terminates in a dummy load, which also serves to attenuate reflected power.

In a third such embodiment, one 3-port circulator is used to feed the feedback or locking signal into the self oscillating tube, the system further comprising:
one 3-port circulator having a first port in communication with the self oscillating tube, a second port in communication with the linear accelerator, and a third port in communication with a feedback line;
a pick-up probe fitted into the accelerating cavity of the linear accelerator in communication with the third port of the 3-port circulator via the feedback line; and
a tuned cavity or band pass filter, an adjustable phase shifter, and either a coaxial isolator or circulator terminating in a dummy load, all in the feedback line.

In another exemplary embodiment of the inventive system, the linear accelerator is a traveling wave accelerator.

When the microwave power source(s) is an amplifier, the microwave power sample from the traveling wave accelerator is used to drive the amplifier, the inventive system further comprising:
a dummy load attached to an exit port of the traveling wave accelerator, wherein unused power exiting the exit port of the accelerator is used as a feedback signal, the exit port in communication with the amplifier either directly via a feedback line or indirectly via a feedback line and a 3-port circulator;
optionally, a 3-port circulator having a first port in communication with the amplifier, a second port in communication with the accelerator, and a third port in communication with the feedback line; and
a tuned cavity or band pass filter, an adjustable phase shifter, and an attenuator in the feedback line.

When the microwave power source(s) is a self oscillating tube, the microwave power sample from the traveling wave accelerator is used to lock the tube's resonant frequency, the inventive system further comprising:
a 3-port circulator having a first port in communication with the self oscillating tube, a second port in communication with the accelerator, and a third port in communication with a feedback line;
a dummy load attached to an exit port of the traveling wave accelerator, wherein unused power exiting the exit port of the accelerator is used as the feedback signal, the exit port in communication with the third port of the 3-port circulator via the feedback line; and
a tuned cavity or band pass filter, an adjustable phase shifter, and either a coaxial isolator or circulator terminating in a dummy load, all in the feedback line.

The present invention also more particularly provides a method for controlling the frequency of one or more high power microwave power sources, which communicate with a high power linear accelerator, the method comprising:
(a) taking a sample of microwave power from the linear accelerator; and
(b) if the one or more microwave power sources is an amplifier (e.g., klystron, amplitron), using the microwave power sample to drive the one or more microwave power sources, and if the one or more microwave power sources is a self-oscillating microwave power source (e.g., magnetron), using the microwave power sample to lock the microwave power frequency of the one or more microwave power sources.

In an exemplary embodiment of the inventive method, the linear accelerator is a resonant or standing wave accelerator.

When the microwave power source(s) is an amplifier (e.g., a klystron or amplitron) and the microwave power sample from the linear accelerator is used to drive the amplifier, the method further comprises:
collecting the microwave power sample or feedback signal along a center mode or main Pi/2 mode of the linear accelerator, while limiting feedback to the main Pi/2 mode;
matching the phase and amplitude of the feedback signal to the phase and amplitude of the amplifier signal to produce an optimized feedback signal;
feeding the optimized feedback signal to the amplifier to drive the amplifier; and
feeding the high power from the amplifier to the linear accelerator, while protecting the amplifier from reflected power by attenuating the reflected power using either a 3-port or 4-port circulator.

As noted above, when the microwave power source(s) is a self oscillating tube (e.g., a magnetron), the microwave power sample from the linear accelerator is used to lock the tube's power frequency.

In a first such embodiment a 4-port circulator is used to feed the feedback or locking signal into the self oscillating tube, the inventive method further comprising:
feeding power from the self-oscillating tube to the linear accelerator, while protecting the tube from reflected power by attenuating the reflected power using a 4-port circulator, and optionally, one or more coaxial isolators or circulators;
collecting a microwave power sample or feedback signal along a center mode or main Pi/2 mode of the linear accelerator, while limiting feedback to the main Pi/2 mode;
matching the phase of the feedback signal to the phase of the self-oscillating tube signal to produce an optimized feedback signal; and
feeding the optimized feedback signal through the 4-port circulator to the self-oscillating tube to lock the tube's power frequency.

In a second such embodiment, a first and a second 3-port circulator are used, the first 3-port circulator being used to feed the feedback or locking signal into the self oscillating tube, the inventive method further comprising:
feeding power from the self-oscillating tube to the linear accelerator, while protecting the tube from reflected power by attenuating the reflected power using the second 3-port circulator;
collecting a microwave power sample or feedback signal along a center mode or main Pi/2 mode of the linear accelerator, while limiting feedback to the main Pi/2 mode;
matching the phase of the feedback signal to the phase of the self-oscillating tube signal to produce an optimized feedback signal; and
feeding the optimized feedback signal through the first 3-port circulator to the self-oscillating tube to lock the tube's power frequency.

In a third such embodiment, one 3-port circulator is used to feed the feedback or locking signal into the self oscillating tube, the inventive method further comprising:
feeding power from the self-oscillating tube to the linear accelerator, while protecting the tube from reflected power by attenuating the reflected power using the 3-port circulator;
collecting a microwave power sample or feedback signal along a center mode or main Pi/2 mode of the linear accelerator, while limiting feedback to the main Pi/2 mode;
matching the phase of the feedback signal to the phase of the self-oscillating tube signal to produce an optimized feedback signal; and
feeding the optimized feedback signal through the 3-port circulator to the self-oscillating tube to lock the tube's power frequency.

In another exemplary embodiment of the inventive method, the linear accelerator is a traveling wave accelerator.

When the microwave power source(s) is an amplifier, the microwave power sample from the linear accelerator is used to drive the amplifier, the inventive method further comprises:
feeding power from the amplifier to the traveling wave accelerator;
using unused power exiting an exit port of the accelerator as a feedback signal, while limiting feedback to the accelerator;
matching the phase and amplitude of the feedback signal to the phase and amplitude of the amplifier signal to produce an optimized feedback signal; and
feeding the optimized feedback signal either directly to the amplifier or through a 3-port circulator to the amplifier to drive the amplifier.

When the microwave power source(s) is a self oscillating tube, the microwave power sample from the accelerator is used to lock the tube's resonant frequency, the inventive method further comprises:
feeding power from the self oscillating tube through a 3-port circulator to the traveling wave accelerator;
using unused power exiting an exit port of the accelerator as a feedback signal, while limiting feedback to the accelerator;
matching the phase of the feedback signal to the phase of the tube signal to produce an optimized feedback signal; and
feeding the optimized feedback signal through the 3-port circulator to the tube to lock the tube's resonant frequency.

Other features and advantages of the invention will be apparent to one of ordinary skill from the following detailed description and accompanying drawings.

Unless otherwise defined, all technical and scientific terms used herein have the same meaning as commonly understood by one of ordinary skill in the art to which this invention belongs. All publications, patent applications, patents and other references mentioned herein are incorporated by reference in their entirety. In case of conflict, the present specification, including definitions, will control. In addition, the materials, methods, and examples are illustrative only and not intended to be limiting.

### BRIEF DESCRIPTION OF THE DRAWINGS

The present disclosure may be better understood with reference to the following drawings. Matching reference numerals designate corresponding parts throughout the drawings, and components in the drawings are not necessarily to scale, emphasis instead being placed upon clearly illustrating the principles of the present disclosure. While exemplary embodiments are disclosed in connection with the drawings, there is no intent to limit the present disclosure to the embodiment or embodiments disclosed herein. On the contrary, the intent is to cover all alternatives, modifications and equivalents.

Particular features of the disclosed invention are illustrated by reference to the accompanying drawings in which:

FIG. 1 is a simplified schematic plan view of an exemplary embodiment of the system of the present invention where a high power linear accelerator is used as a frequency control element for one or more high power sources of microwaves;

FIG. 2 is a simplified schematic side view of a sampling coupler or pick-up probe located in one of the accelerating cavities of the linear accelerator shown in FIG. 1, while FIG. 2a is an enlarged view of the encircled area shown in FIG. 2;

FIG. 3a is a simplified schematic side view of a 3-port circulator used in exemplary embodiments of the present invention, while FIG. 3b is a simplified schematic side view of a 4-port circulator;

FIG. 4 is a simplified schematic plan view of an exemplary embodiment of the inventive system where the linear accelerator is a resonant or standing wave accelerator and the one or more high power sources of microwaves is an amplifier (e.g., a klystron or amplitron);

FIG. 5 is a simplified schematic plan view of an exemplary embodiment of the inventive system where the linear accelerator is a resonant or standing wave accelerator, the one or more high power sources of microwaves is a self oscillating tube (e.g., a magnetron), and a 4-port circulator is used to feed a feedback or locking signal into the self oscillating tube;

FIG. 6 is a simplified schematic plan view of an exemplary embodiment of the inventive system, which is similar in design to the system shown in FIG. 5, but which employs two 3-port circulators, one of which is used to feed a feedback or locking signal into the self oscillating tube;

FIG. 7 is a simplified schematic plan view of an exemplary embodiment of the inventive system, which is also similar in design to the system shown in FIG. 5, but which employs one 3-port circulator to feed a feedback or locking signal into the self oscillating tube;

FIG. 8 is a simplified schematic plan view of an exemplary embodiment of the inventive system where the linear accelerator is a traveling wave accelerator and the one or more high power sources of microwaves is an amplifier; and

FIG. 9 is a simplified schematic plan view of an exemplary embodiment of the inventive system where the linear accelerator is a traveling wave accelerator, the one or more high power sources of microwaves is a self oscillating tube, and a 3-port circulator is used to feed a feedback or locking signal into the self oscillating tube.

### DETAILED DESCRIPTION OF THE INVENTION

As previously mentioned, the present invention provides a new frequency control for high power microwave sources, where the accelerator itself functions as the control element. The inventive method and system serve to provide and maintain the required drive frequency to a linear accelerator within a very narrow range.

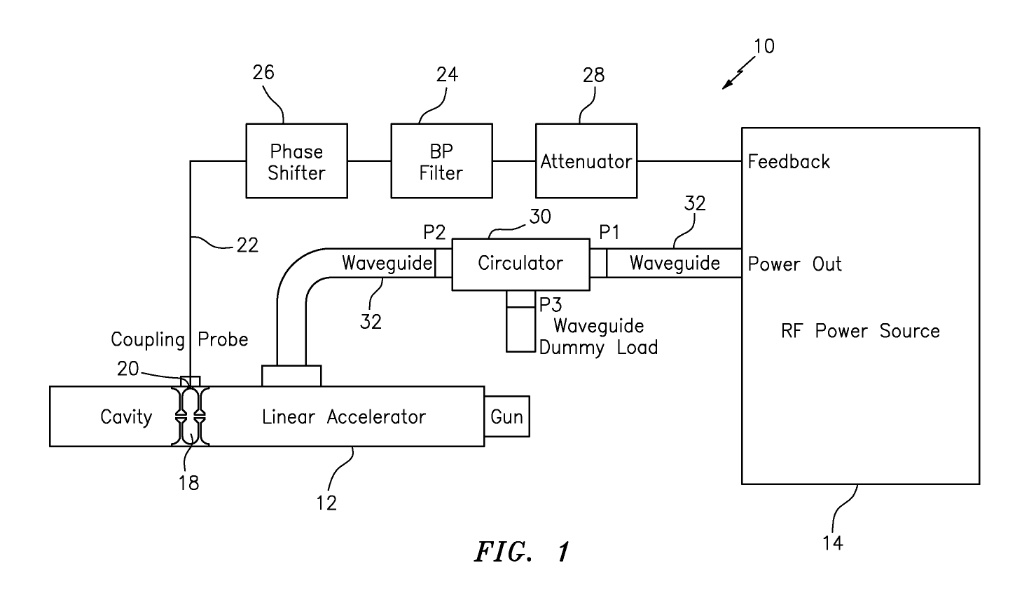

Referring now to the drawings in detail, an exemplary embodiment of the system of the present invention is shown in FIG. 1, marked with reference numeral 10. In the inventive system 10, a high power linear accelerator 12 is used as a frequency control element for a high power source of microwaves 14. System 10 takes a sample of microwave power from the accelerator 12 and uses this to provide a drive or locking signal for the high power microwave source 14. If the microwave power source 14 is an amplifier such as a klystron or amplitron the signal is used to drive the amplifier. If the microwave power source 14 is a self oscillating tube such as a magnetron the signal is used to lock the microwave power frequency.

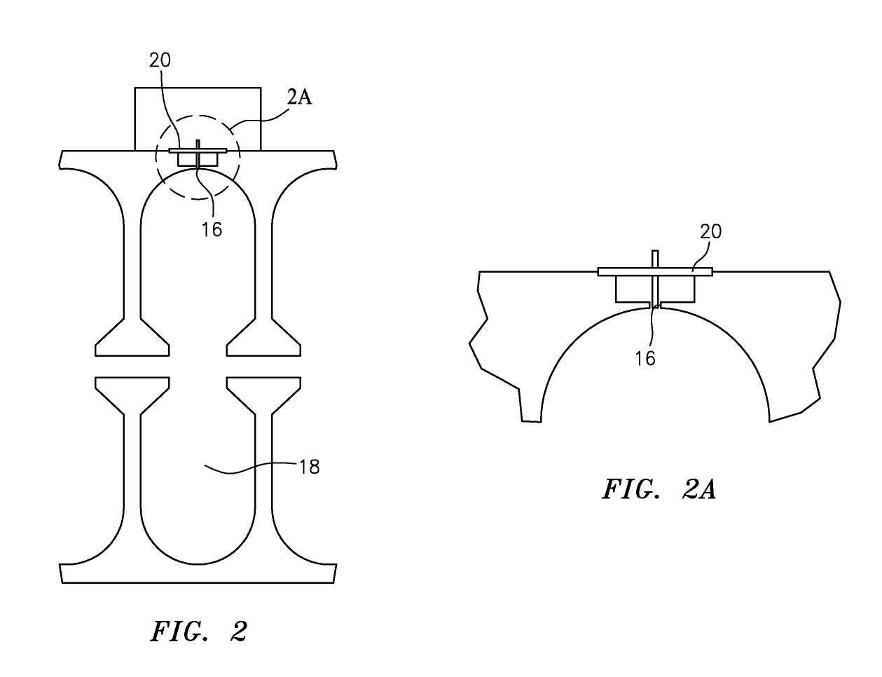

As best shown in FIGS. 2 and 2a, the microwave power sample is typically taken by a small hole or iris 16 in one of the accelerating cavities 18 of the high power linear accelerator 12. A sampling coupler or pick-up probe 20 fitted into the small hole or iris 16 of accelerating cavity 18 allows a sample of the power in the cavity to escape along a feedback line 22 leading from the accelerator 12 to the high power source of microwaves 14. The power level in this sampling circuit is typically between about 30 to about 50 decibels (dB) less than the power in the cavity 18. The cavity power is typically several hundred kilowatts and the sample power is from about 30 to about 50 dB less than this (i.e., several hundreds to thousands of watts).

In the exemplary embodiment shown in FIG. 1, the microwave power sample is taken from the center mode or Pi/2 mode. As will be readily appreciated by those skilled in the art, a linear accelerator is a set of tuned microwave cavities having a multitude of resonant frequencies, one for each accelerating cavity and one for each coupling cavity. For example, an accelerator with eight (8) accelerator cavities and seven (7) coupling cavities has a mode spectrum of fifteen (15) resonant frequencies or modes. An accelerator with twenty-five (25) accelerator cavities has a ‘mode spectrum’ of forty-nine (49) modes. The center mode or Pi/2 mode is the mode in which the phase changes by 90 degrees, or ½ pi per circuit element. For a 3 Ghz linear accelerator, the modes typically stretch from 2,925 megahertz (Mhz) to 3,075 Mhz. The modes are further apart in the center but the modes nearest the Pi/2 can be as close as 10 Mhz.

In order to limit feedback to the main Pi/2 mode, the inventive system 10 uses a tuned cavity or band pass filter 24 in the feedback line 22. As the nearest mode can be as close as 10 Mhz away from the Pi/2 frequency then a band pass filter with a pass band ±5 MHz is used.

An adjustable phase shifter 26 and an adjustable attenuator 28 are also positioned in the feedback line 22. As will be appreciated by those skilled in the art, an attenuator is only needed for systems in which the microwave power source 14 is an amplifier (e.g., klystron or amplitron). As alluded to above, the phase shifter allows for necessary adjustments in phase, while the attenuator allows for necessary adjustments in amplitude, thereby allowing for optimization of the feedback signal.

Referring again to FIG. 1, a 3-port circulator 30 is shown positioned along a waveguide 32 leading from the high power source of microwaves 14 to the high power linear accelerator 12. As is known to one skilled in the art, linear accelerators use a high power microwave tube to drive them and a high power isolator is used to protect the tube from reflected power. For resonant or standing wave accelerators there is a significant amount of reflected power as the accelerator fills and empties at the start and end of each drive pulse. For these accelerators, the isolation is a provided by device which separates the reflected power from the forward power together with a separate microwave load to absorb the reflected power. The selection device is the circulator and at least one dummy load is needed to make the circulator an isolator. As will be explained in more detail below, by way of the present invention, when the high power microwave source 14 is a self oscillating tube (e.g., a magnetron), a circulator/isolator is also used to feed the locking signal into the tube.

A circulator is basically used to shunt power coming in one port to the next port with no power going to the other one or more ports. So although the description uses port numbers in connection with these devices, the ports are actually interchangeable and one can use, for example, port 2 (P2) as the input and thus port 3 (P3) as the output, etc. It is however important to maintain the sequence.

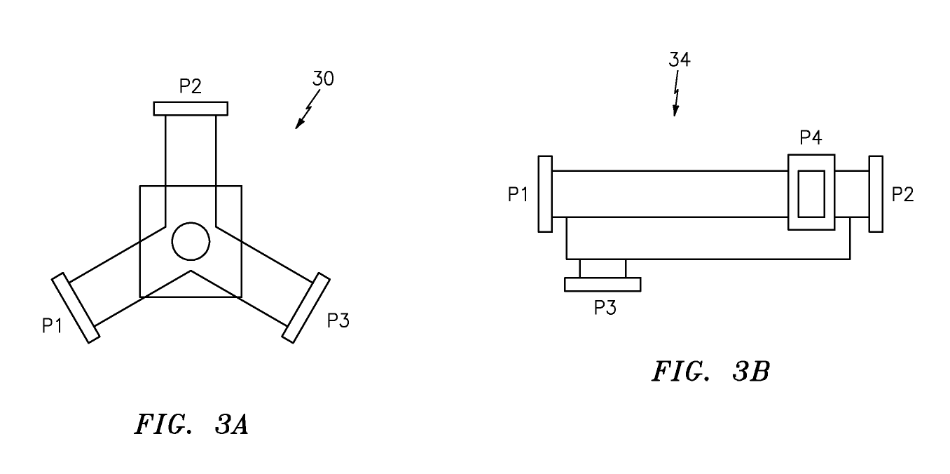

There are two different types of circulators, a 3-port circulator 30, which is shown in both FIG. 1 and FIG. 3a, and a 4-port circulator 34, which is shown in FIG. 3b. The 3-port circulator 30 takes power in at port 1 (P1) and sends it out at port 2 (P2). Power in at port 2 (P2) comes out at port 3 (P3) and power in at port 3 (P3) comes out at port 1 (P1). In other words, the circulator accepts power at any port and sends it out from the adjacent port with none (or some small leakage) through other ports. The 3-port circulator has one dummy load on one port when used as an isolator, with isolation usually specified at from about −25 to about −30 dB (i.e., 0.25 to 0.1%). Three (3)-port circulators are significantly smaller and less expensive than 4-port circulators.

The 4-port circulator 34 accepts power in at port 1 (P1) and directs it out through port 2 (P2). Power coming in at port 2 (P2) comes out at port 3 (P3). Power coming in at port 3 (P3) comes out at port 4 (P4) and power coming in at port 4 (P4) goes out at port 1 (P1). The 4-port circulator has a dummy load on one or more ports when used as an isolator, with isolation usually specified at from about −35 to about −30 dB (i.e., 0.025 to 0.1%).

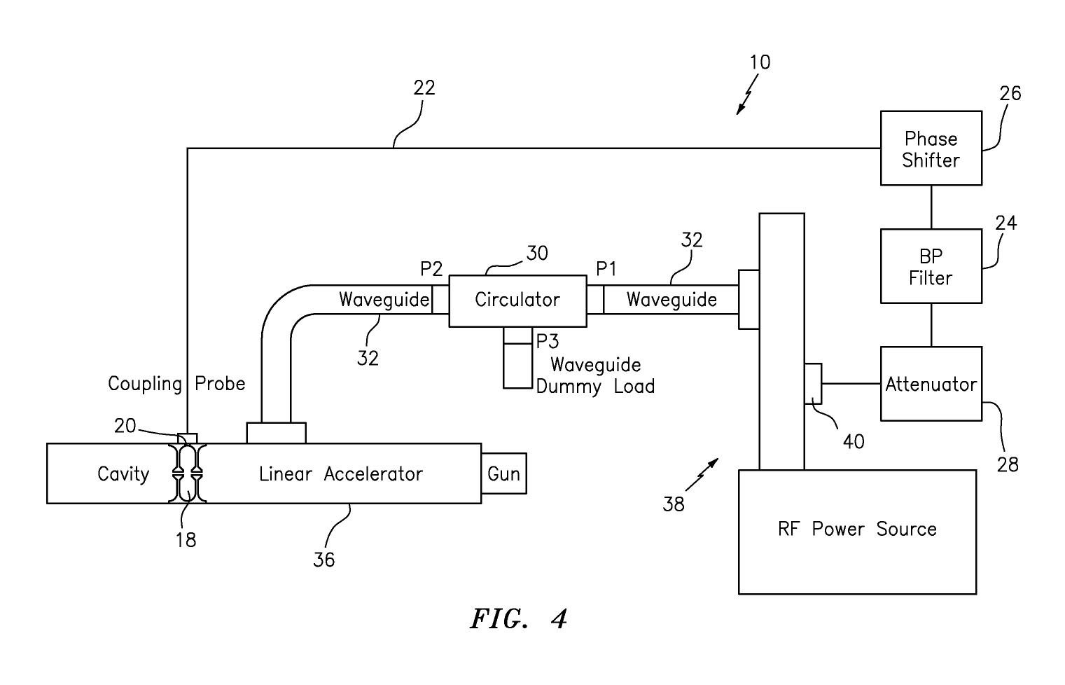

In FIG. 4, an exemplary embodiment of the inventive system is shown where the linear accelerator is a resonant or standing wave accelerator 36, and where the one or more high power sources of microwaves is a klystron 38. As noted above, if a high power amplifier, such as a klystron, is used in the inventive system and a sample of power in the accelerator is taken, the klystron can be made to oscillate at the accelerator frequency, provided the feedback signal is sufficient to drive the power device. The feedback signal must also be of the correct phase to provide maximum gain.

In the system shown in FIG. 4, a pickup probe 20 fitted into an accelerating cavity 18 of accelerator 36 is used to collect a sample of the power. In this exemplary embodiment, a range of from about 100 to about 300 watts of power is sufficient to drive the klystron 38. A typical gain for a klystron ranges from about 40 to about 50 dB (i.e., 10,000 to 100,000 times or more), so the drive signal for an output ranging from about 2 to about 6 MW is from about 20 to about 600 watts. The sample of power is fed to a klystron input 40 along feedback line 22 through adjustable phase shifter 26, band pass filter 24, and adjustable attenuator 28. The adjustable phase shifter 26 is used to provide feedback with the correct phase to the klystron, while the band pass filter 24 limits feedback to the linear accelerator 12 Pi/2 frequency. The attenuator 28 is used to adjust the amplitude of the feedback signal into the klystron so as to avoid overdriving the klystron. In other words, the feedback signal is adjusted to an appropriate phase and amplitude in order to more effectively drive the klystron. The high power from the klystron 38 is fed to the accelerator 36 along waveguide 32 through high power 3-port circulator 30. The circulator 30 has a dummy load on port 3 (P3) and is used as an isolator to attenuate reflected power from the accelerator 36 to protect the klystron 38. In this exemplary embodiment, the circulator has no other function and can be either a 3-port or a 4-port circulator.

While a klystron is used in the exemplary embodiment above, the invention is not so limited. Any type of microwave amplifier can be used in the present invention including, but not limited to, an amplitron, reltron, or triode.

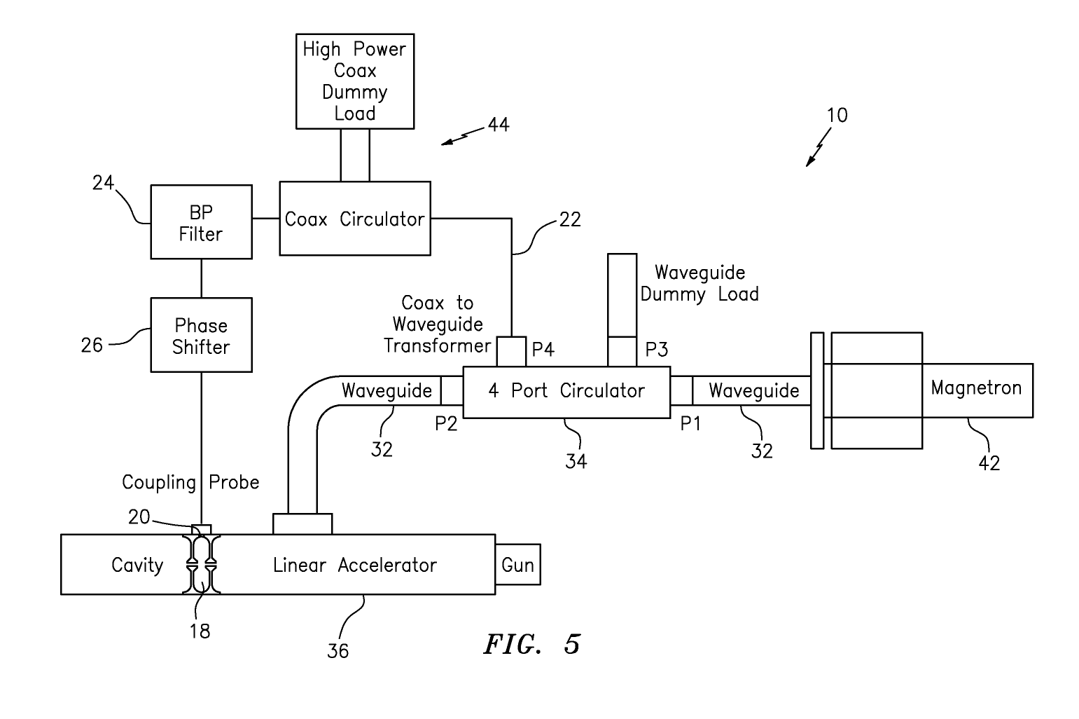

In FIG. 5, a self-oscillating tube in the form of a magnetron 42 is used as the high power microwave source. Here, the inventive system 10 is made up of a resonant accelerator 12, the magnetron 42, and a 4-port circulator 34 that serves to direct the feedback signal into the magnetron.

The magnetron is itself a power oscillator with its own resonant frequency. The required operating frequency must be close to the magnetron's natural resonant frequency. In this exemplary embodiment, the feedback signal is obtained as before from pickup probe 20 fitted into accelerating cavity 18 of accelerator 36. The feedback signal travels along feedback line 22 into port 4 (P4) of the 4-port circulator 34 and out port 1 (P1) into the magnetron 42. The present inventors have determined that a locking signal strength of from about 2 to about 5 kW is sufficient to lock the microwave power frequency.

More specifically, during operation of the inventive system, power from the magnetron 42 travels along waveguide 32, enters port 1 (P1) of the 4-port circulator 34, leaves through port 2 (P2) of the circulator, and travels along the waveguide 32 to the accelerator 36. Reflected power from the accelerator enters the circulator at port 2 (P2) and leaves from port 3 (P3). Port 3 (P3) has a dummy load, which effectively reflects no power. Thus, there is no power going back into port 3 (P3) and none leaving port 4 (P4). The feedback signal is fed into port 4 (P4), which causes it to go into the magnetron 42.

Where neither a dummy load nor isolator is perfect, a separate coaxial isolator or a circulator with a dummy load 44 is added to feedback line 22, in addition to phase shifter 26 and filter 24.

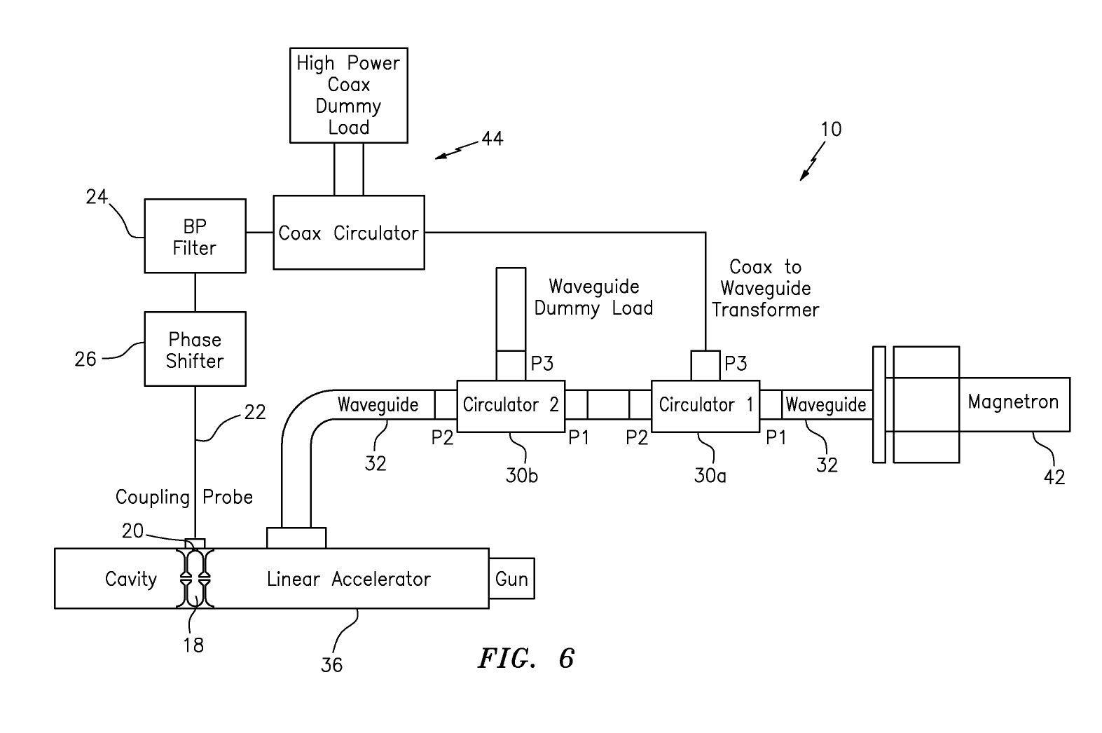

In FIG. 6, another exemplary embodiment of the inventive system is shown, which utilizes two 3-port circulators, one of which is used to direct the feedback signal into the magnetron.

In operation, power from the magnetron travels along waveguide 32, enters port 1 (P1) of the first 3-port circulator 30a, leaves through port 2 (P2) of the circulator, enters port 1 (P1) of the second 3-port circulator 30b, leaves through port 2 (P2) of the circulator, and travels along the waveguide to the accelerator 36. Reflected power from the accelerator 36 enters the second circulator 30b at port 2 (P2) and comes out of port 3 (P3). Port 3 (P3) has a dummy load, so no power goes into this port and thus no power goes out of port 1 (P1) of the second circulator 30b and into port 2 (P2) of the first circulator 30a. The feedback signal is fed into port 3 (P3) of the first circulator 30a, and thus exits port 1 (P1) of the first circulator into the magnetron 42. Again, phase shifter 26, filter 24 and coaxial circulator/high power coaxial dummy load combination 44 are used in the feedback line 22.

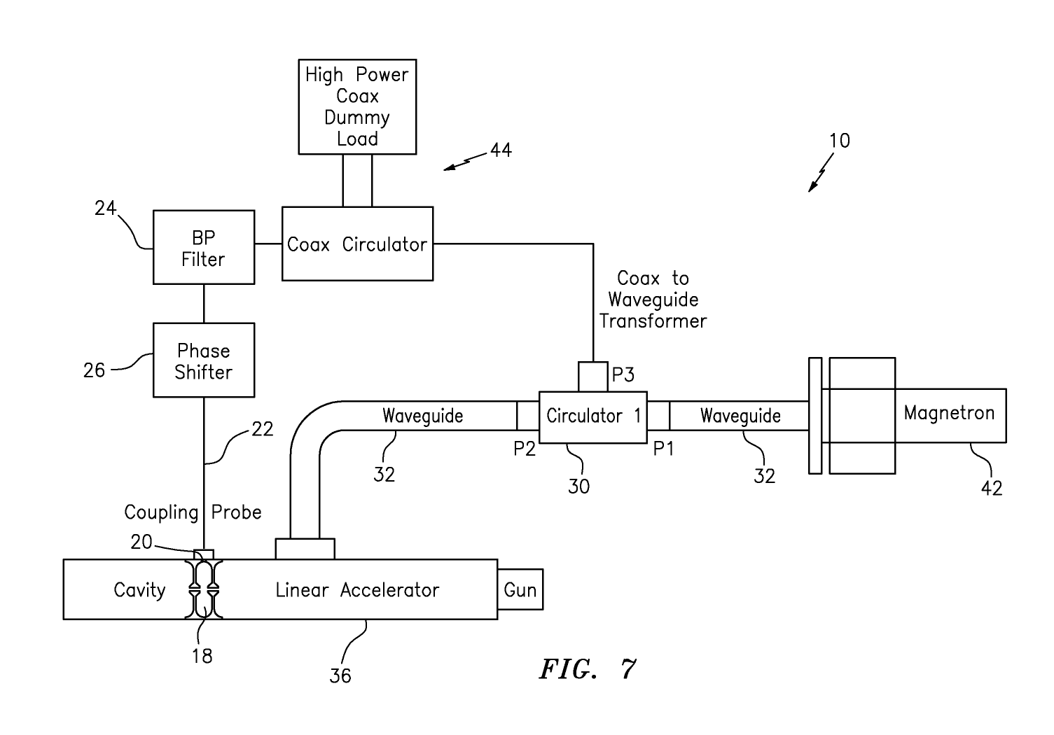

As will be appreciated by those skilled in the art, it would be possible to use just one 3-port circulator for low power operation and/or a high power coaxial isolator in the feedback or drive line. One such example of the inventive system is shown in FIG. 7. In the operation of this system, the feedback signal is fed into port 3 (P3) of 3-port circulator 30, which does not act as an isolator, and exits port 1 (P1) of the circulator into the magnetron 42. Coaxial circulator/high power coaxial dummy load combination 44 is used in the feedback line 22.

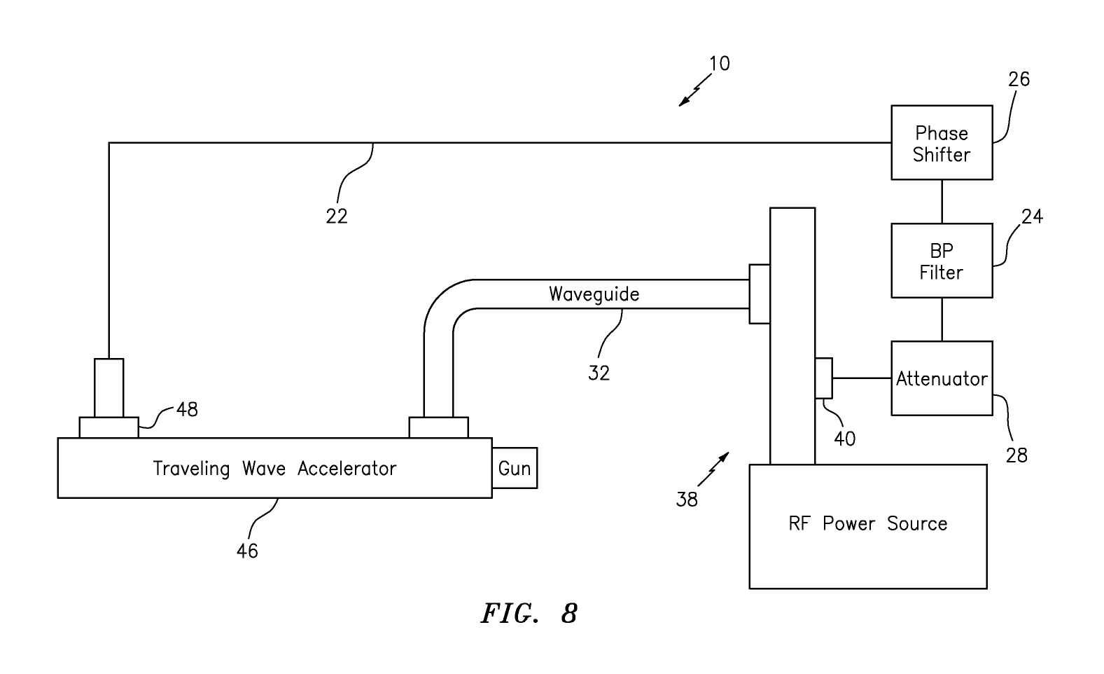

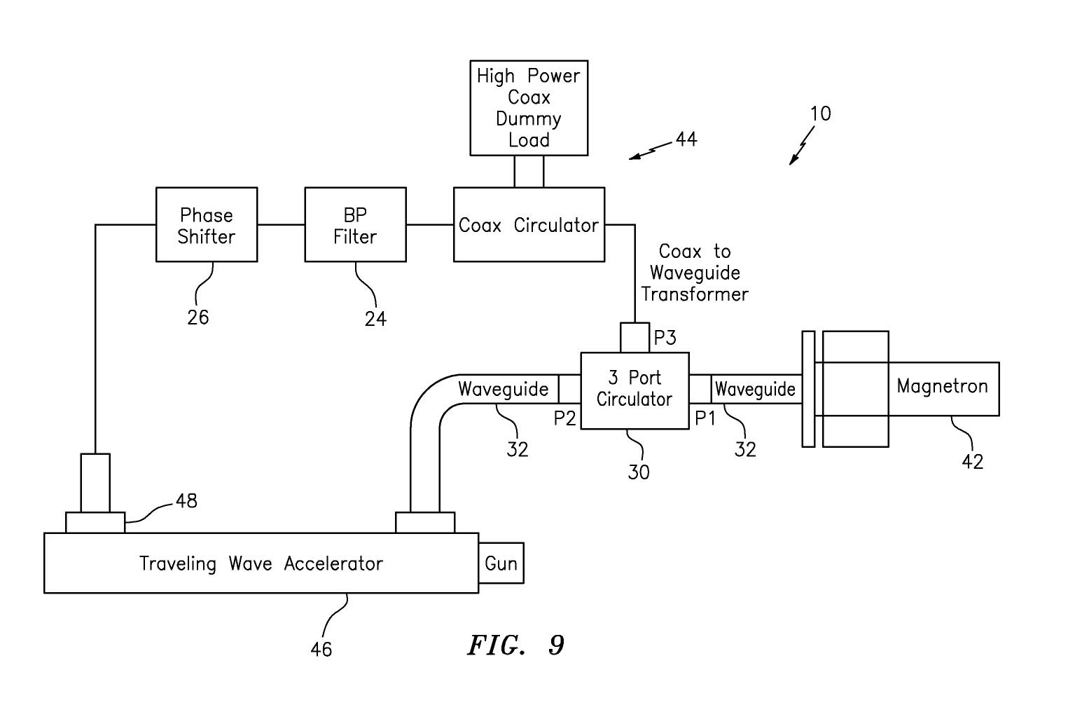

Another exemplary embodiment of the inventive system is shown in FIG. 8, where the linear accelerator is a traveling wave accelerator 46 and the one or more high power sources of microwaves is a klystron 38. Here a traveling wave structure is used to accelerate the particles. In this type of structure, electrons travel down a circular waveguide with resonant iris or other structures to form high electric fields. Although this type of structure does not exhibit a resonant signature with a very sharp acceptance of RF power the useful band of frequencies almost as limited as the resonant structure. In this type of accelerator the RF power enters the structure at one end and unused power exits at the other end (i.e., exit port 48). A dummy load is attached to the exit port 48. This exit power is sampled and used as the feedback signal in the same way as the pickup probe in a resonant accelerator. This is shown in FIGS. 8 and 9. In fact, the amount of input reflected power in a traveling wave accelerator is much less than the standing wave machine and a circulator may not be needed for isolation for the klystron application and only one circulator would be needed for the magnetron, as shown in FIG. 9.

While various embodiments of the present invention have been described above, it should be understood that they have been presented by way of example only, and not limitation. Thus, the breadth and scope of the present invention should not be limited by any of the exemplary embodiments.

We claim:

1. A system comprising a high power linear accelerator, and connected thereto, one or more high power sources of microwaves, wherein a sample of microwave power from the linear accelerator is used to provide a locking or drive signal for the one or more high power sources of microwaves.

2. The system of claim 1, wherein the high power linear accelerator is a resonant or standing wave accelerator.

3. The system of claim 2, wherein the one or more microwave power sources is an amplifier, wherein the microwave power sample from the linear accelerator is used to drive the amplifier, the system further comprising:
a pick-up probe fitted into an accelerating cavity of the linear accelerator to collect the microwave power sample or feedback signal along a center mode or main Pi/2 mode of the linear accelerator, the pick-up probe in communication with the amplifier via a feedback line;
a tuned cavity or band pass filter in the feedback line for limiting feedback to the main Pi/2 mode of the linear accelerator;
an adjustable phase shifter in the feedback line for adjustably providing a 360 degree range of phase shift to the feedback signal;
an attenuator in the feedback line for adjusting amplitudes of the feedback signal; and
a high power circulator having one or more ports terminating in a dummy load, which is in communication with both the linear accelerator and the amplifier, and which is used as an isolator to attenuate reflected power, thereby protecting the amplifier.

4. The system of claim 2, wherein the one or more microwave power sources is a self oscillating tube, wherein the microwave power sample from the linear accelerator is used to lock the tube's resonant frequency.

5. The system of claim 4, wherein a 4-port circulator is used to feed the feedback signal into the self oscillating tube, the system further comprising:
a 4-port circulator having a first port in communication with the self oscillating tube, a second port in communication with the linear accelerator, a third port having a dummy load to attenuate reflected power, and a fourth port in communication with a feedback line;
a pick-up probe fitted into an accelerating cavity of the linear accelerator to collect the microwave power sample or feedback signal along a center mode or main Pi/2 mode of the linear accelerator, the pick-up probe in communication with the 4-port circulator via the feedback line;
a tuned cavity or band pass filter in the feedback line for limiting feedback to the main Pi/2 mode of the linear accelerator;
an adjustable phase shifter in the feedback line for adjustably providing a 360 degree range of phase shift to the feedback signal; and
either a coaxial isolator or circulator in the feedback line, which terminates in a dummy load, which also serves to attenuate reflected power.

6. The system of claim 4, wherein two 3-port circulators are used, the first 3-port circulator being used to feed the feedback or locking signal into the self oscillating tube, the system further comprising:
a first 3-port circulator having a first port in communication with the self oscillating tube, a second port, and a third port in communication with a feedback line;
a second 3-port circulator having a first port in communication with the second port of the first 3-port circulator, a second port in communication with the linear accelerator, and a third port terminating in a dummy load to attenuate reflected power;
a pick-up probe fitted into an accelerating cavity of the linear accelerator to collect the microwave power sample or feedback signal along a center mode or main Pi/2 mode of the linear accelerator, the pick-up probe in communication with the third port of the first 3-port circulator via the feedback line;
a tuned cavity or band pass filter in the feedback line for limiting feedback to the main Pi/2 mode of the linear accelerator;
an adjustable phase shifter in the feedback line for adjustably providing a 360 degree range of phase shift to the feedback signal; and
either a coaxial isolator or circulator in the feedback line, which terminates in a dummy load, which also serves to attenuate reflected power.

7. The system of claim 4, wherein one 3-port circulator is used to feed the feedback or locking signal into the self oscillating tube, the system further comprising:
one 3-port circulator having a first port in communication with the self oscillating tube, a second port in communication with the linear accelerator, and a third port in communication with a feedback line;
a pick-up probe fitted into the accelerating cavity of the linear accelerator in communication with the third port of the 3-port circulator via the feedback line; and
a tuned cavity or band pass filter, an adjustable phase shifter, and either a coaxial isolator or circulator terminating in a dummy load, all in the feedback line.

8. The system of claim 1, wherein the high power linear accelerator is a traveling wave accelerator.

9. The system of claim 8, wherein the one or more microwave power sources is an amplifier, wherein the microwave power sample from the traveling wave accelerator is used to drive the amplifier, the system further comprising:
a dummy load attached to an exit port of the traveling wave accelerator, wherein unused power exiting the exit port of the accelerator is used as a feedback signal, the exit port in communication with the amplifier either directly via a feedback line or indirectly via a feedback line and a 3-port circulator;
optionally, a 3-port circulator having a first port in communication with the amplifier, a second port in communication with the accelerator, and a third port in communication with the feedback line; and
a tuned cavity or band pass filter, an adjustable phase shifter, and an attenuator in the feedback line.

10. The system of claim 8, wherein the one or more microwave power sources is a self oscillating tube, wherein the microwave power sample from the traveling wave accelerator is used to lock the tube's resonant frequency, the system further comprising:
a 3-port circulator having a first port in communication with the self oscillating tube, a second port in communication with the accelerator, and a third port in communication with a feedback line;
a dummy load attached to an exit port of the traveling wave accelerator, wherein unused power exiting the exit port of the accelerator is used as the feedback signal, the exit port in communication with the third port of the 3-port circulator via the feedback line; and
a tuned cavity or band pass filter, an adjustable phase shifter, and either a coaxial isolator or circulator terminating in a dummy load, all in the feedback line.

11. A method for controlling the frequency of one or more high power microwave power sources, which communicate with a high power linear accelerator, the method comprising:
(a) taking a sample of microwave power from the linear accelerator; and
(b) if the one or more microwave power sources is an amplifier, using the microwave power sample to drive the one or more microwave power sources, and if the one or more microwave power sources is a self-oscillating microwave power source, using the microwave power sample to lock the microwave power frequency of the one or more microwave power sources.

12. The method of claim 11, wherein the linear accelerator is a resonant or standing wave accelerator.

13. The method of claim 12, wherein the one or more microwave power sources is an amplifier, wherein the microwave power sample from the linear accelerator is used to drive the amplifier, the method further comprising:
collecting the microwave power sample or feedback signal along a center mode or main Pi/2 mode of the linear accelerator, while limiting feedback to the main Pi/2 mode;
matching the phase and amplitude of the feedback signal to the phase and amplitude of the amplifier signal to produce an optimized feedback signal;
feeding the optimized feedback signal to the amplifier to drive the amplifier; and
feeding the high power from the amplifier to the linear accelerator, while protecting the amplifier from reflected power by attenuating the reflected power using either a 3-port or 4-port circulator.

14. The method of claim 12, wherein the one or more microwave power sources is a self oscillating tube, wherein the microwave power sample from the linear accelerator is used to lock the tube's power frequency.

15. The method of claim 14, wherein a 4-port circulator is used to feed the feedback or locking signal into the self oscillating tube, the method further comprising:
feeding power from the self-oscillating tube to the linear accelerator, while protecting the tube from reflected power by attenuating the reflected power using a 4-port circulator, and optionally, one or more coaxial isolators or circulators;
collecting a microwave power sample or feedback signal along a center mode or main Pi/2 mode of the linear accelerator, while limiting feedback to the main Pi/2 mode;
matching the phase of the feedback signal to the phase of the self-oscillating tube signal to produce an optimized feedback signal; and
feeding the optimized feedback signal through the 4-port circulator to the self-oscillating tube to lock the tube's power frequency.

16. The method of claim 14, wherein a first and a second 3-port circulator are used, wherein the first 3-port circulator is used to feed the feedback or locking signal into the self oscillating tube, the method further comprising:
feeding power from the self-oscillating tube to the linear accelerator, while protecting the tube from reflected power by attenuating the reflected power using the second 3-port circulator;
collecting a microwave power sample or feedback signal along a center mode or main Pi/2 mode of the linear accelerator, while limiting feedback to the main Pi/2 mode;
matching the phase of the feedback signal to the phase of the self-oscillating tube signal to produce an optimized feedback signal; and
feeding the optimized feedback signal through the first 3-port circulator to the self-oscillating tube to lock the tube's power frequency.

17. The method of claim 14, wherein one 3-port circulator is used to feed the feedback or locking signal into the self oscillating tube, the method further comprising:
feeding power from the self-oscillating tube to the linear accelerator, while protecting the tube from reflected power by attenuating the reflected power using the 3-port circulator;
collecting a microwave power sample or feedback signal along a center mode or main Pi/2 mode of the linear accelerator, while limiting feedback to the main Pi/2 mode;
matching the phase of the feedback signal to the phase of the self-oscillating tube signal to produce an optimized feedback signal; and
feeding the optimized feedback signal through the 3-port circulator to the self-oscillating tube to lock the tube's power frequency.

18. The method of claim 11, wherein the linear accelerator is a traveling wave accelerator.

19. The method of claim 18, wherein the one or more microwave power sources is an amplifier, wherein the microwave power sample from the linear accelerator is used to drive the amplifier, the method further comprising:
feeding power from the amplifier to the traveling wave accelerator;
using unused power exiting an exit port of the accelerator as a feedback signal, while limiting feedback to the accelerator;
matching the phase and amplitude of the feedback signal to the phase and amplitude of the amplifier signal to produce an optimized feedback signal; and
feeding the optimized feedback signal either directly to the amplifier or through a 3-port circulator to the amplifier to drive the amplifier.

20. The method of claim 18, wherein the one or more microwave power sources is a self oscillating tube, wherein the microwave power sample from the accelerator is used to lock the tube's resonant frequency, the method further comprising:
feeding power from the self oscillating tube through a 3-port circulator to the traveling wave accelerator;
using unused power exiting an exit port of the accelerator as a feedback signal, while limiting feedback to the accelerator;
matching the phase of the feedback signal to the phase of the tube signal to produce an optimized feedback signal; and
feeding the optimized feedback signal through the 3-port circulator to the tube to lock the tube's resonant frequency.
